(19) United States
(12) Patent Application Publication
(10) Pub. No.: US 2023/0275396 A1
(43) Pub. Date: Aug. 31, 2023

(54) BACK-PUMPED SEMICONDUCTOR MEMBRANE LASER

(71) Applicant: TWENTY-ONE SEMICONDUCTORS GMBH, Neckartenzlingen (DE)

(72) Inventors: Roman Andreas Bek, Böblingen (DE); Norbert Witz-Haszler, Stuttgart (DE)

(73) Assignee: TWENTY-ONE SEMICONDUCTORS GMBH, Neckartenzlingen (DE)

(21) Appl. No.: 18/010,289

(22) PCT Filed: Jun. 25, 2021
(86) PCT No.: PCT/EP2021/067461

§ 371 Date: Dec. 14, 2022

(30) Foreign Application Priority Data
Jul. 1, 2020 (DE) 10 2020 003 969.3

(51) Int. Cl. H01S 5/024; H01S 5/023; H01S 5/0237; H01S 5/04; H01S 5/20; H01S 5/323

(52) U.S. Cl. CPC H01S 5/02476; H01S 5/023; H01S 5/0237; H01S 5/041; H01S 5/2027; H01S 5/323

(57) ABSTRACT

A semiconductor membrane laser chip includes a planar-shaped lasing medium having an upper surface and a lower surface opposite the upper surface, the lasing medium configured to emit electromagnetic radiation at a laser wavelength λ₁. A first heat spreader is bonded to one of the upper surface and the lower surface of the lasing medium. A first dielectric layer is arranged on the lower surface of the lasing medium or arranged on a lower surface of the first heat spreader when the first heat spreader is bonded to the lower surface of the lasing medium. The first dielectric layer is reflective for the laser wavelength λ₁.

### CROSS-REFERENCE TO RELATED APPLICATIONS

This application is the United States national stage patent application of International Application No. PCT/EP2021/067461 filed on Jun. 25, 2021, which claims priority to German Patent Application No. DE 10 2020 003 969.3 filed on Jul. 1, 2020, the entire disclosure of which are hereby incorporated by reference.

### FIELD OF THE INVENTION

The invention belongs to the field of photonics and in particular to the field of semiconductor lasers.

### BACKGROUND OF THE INVENTION

As is known in the art, optically pumped semiconductor lasers, e.g. implemented as vertically emitting semiconductor lasers provide high output power and excellent beam properties over a wide range of wavelengths. In addition, the provision of an external resonator arranged externally to the semiconductor laser chip will enable the operation of the semiconductor laser to be influenced by optical elements in order to achieve, for example, a narrow line width, a tunable emission wavelength, efficient frequency conversion and/or the emission of ultrashort pulses of laser light.

However, depending on the wavelength of emission of the laser light and thus also on the material system of the amplifier medium in the semiconductor laser, the implementation of this laser concept is currently only possible with a great deal of technical and financial effort. Currently large pump sources need to be used, and expensive individual heat spreaders need to be installed to dissipate thermal energy generated within the semiconductor laser. The thermal contact between the semiconductor amplifier medium and the heat spreader is poor in the prior art semiconductor lasers.

One reason for this substantial technical effort is the lack of availability of cheap pump sources for the semiconductor laser. The pump sources require good beam quality over a wide range of wavelengths and so expensive pump optics need to be used to focus the pump beam from the pump laser to a pump spot in the semiconductor laser. However, the combination of the size of a focusing lens in the pump optics and a required minimum distance from the focusing lens to the pump spot is limited geometrically by the 900 angle between the amplifier medium in the semiconductor laser and the generated laser beam in the resonator.

This can be illustrated in FIG. 1 which shows a semiconductor disk laser having a semiconductor disk laser chip 10 with a heat spreader 20, an active region 30 with the amplifier medium and a Bragg reflector 40. Pump laser light 50 from a pump source laser 60 impinges on a pump spot 35 from a side 15. The pump laser light 50 causes lasing within the active region 30 leading to generation of laser light 70 from an upper face 12 of the semiconductor disk laser chip 10. The laser light 75 is coupled out of the semiconductor disk laser by a mirror 80. In order to achieve lasing within the active region 30, an expensive, well-focusable pump source laser 60 must be used, or the active region 30 will be pumped over too large a range. As a result, more pump power in the pump laser light 50 will be required to achieve the required power density in the active region 30 to cause lasing and this will also result in additional heat being generated in the active region 30, which in turn requires increased pump power density and additionally reduces the output power of the lasing medium in the active region 30.

Another issue relates to heat management in such semiconductor lasers, especially in optically pumped, vertically emitting semiconductor lasers. There are three different approaches that can be adopted to deal with the dispersal of heat (thermal energy) in such semiconductor lasers. A first solution is shown in FIG. 1 in which the heat from the amplifier medium in the active region 30 is transferred via a semiconductor mirror (the Bragg reflector 40) into the heat spreader 20 (which is made, for example, from diamond). Depending on the wavelength range of the semiconductor disk laser—and thus the material system of the semiconductor mirror—the heat dissipation is very limited due to the low thermal transmission through the Bragg reflector 40.

Another solution is shown in FIG. 2 which shows a semiconductor disk laser with an intra-cavity heat spreader 220. The heat spreader 220 (which is also of diamond of very good optical quality) is applied directly to the amplifier medium in the active region 30. This application is done either by a purely mechanical pressure or by a presence of intermediate layers which ensure a permanent mechanical contact between the active region 30 and the heat spreader 220. The Bragg reflector 40 is supported on a substrate 200. In both cases the heat dissipation at the interface 225 between the active region 30 and the heat spreader 220 is also limited.

A third solution is shown in FIG. 3 which illustrates an obliquely (or incline) pumped semiconductor membrane laser. In this newer laser concept, the active region 30 with the amplifying medium is brought into contact with an upper heat spreader 320a and a lower heat spreader 320b located on both sides of the active region 30. This already greatly improves heat dissipation compared to the approach shown in FIG. 2. As an alternative to diamond, the use of silicon carbide as the heat spreader has also been demonstrated. The silicon carbide is brought into direct contact with the amplifier medium in the active region 30 by means of plasma-activated bonding (see Z. Yang et al., “16 W DBR-free membrane semiconductor disk laser with dual-SiC heatspreader,” Electronics Letters, vol. 54, no. 7, pp. 430-432 (2018)). However, the geometric limitation of the pump optics discussed above still exists in this third solution.

The optically pumped, vertically emitting semiconductor laser chips are mounted into or onto so-called submounts to form an amplifier unit which acts as a heat sink connected to the heat spreader in the semiconductor laser, as will be explained below. All of the solutions discussed have required separate production of each individual one of the amplifier units, so that upscaling into a low-cost production process suitable for mass production is limited. For a large number of emission wavelengths, the prior art solutions only therefore allow the manufacture of an optically pumped, vertically emitting semiconductor laser with at least one of the following limitations: a low optical output power due to insufficient thermal management in the amplifier unit, insufficient adaptation of the optical pump to the resonator geometry, and high costs for individual laser systems due to complex heat management, which is not cost-effective for high quantities, or require a cost-intensive special pump source or pump optics. As a result, the prior art solutions offer no advantage (or even disadvantages) in these wavelength ranges compared to other concepts already commercially available.

The prior art solution is therefore unattractive for a large market, and only those solutions shown in FIGS. 1 and 2 are available at individual emission wavelengths and at high unit prices.

### RELATED ART

A number of patent documents and literature articles are known that describe optically pumped, vertically emitting semiconductor lasers and their manufacture. For example, U.S. Pat. No. 8,170,073 B2 (equivalent to PCT Application Publication No. WO 2011/031718 A2) teaches the use of a diamond heat spreader. The design illustrated in this patent document cannot be mass produced at wafer scale.

U.S. Pat. No. 9,124,062 B2 teaches the use of dielectric layers as reflectors in direct contact with the amplifier medium, instead of heat spreaders for efficient heat dissipation. The amplifier medium is a Group III nitride which is on GaN substrate, but no complete substrate removal is taught in this application. The laser wavelength is between 370 nm and 550 nm.

US Patent Application No. US 2013/0028279 A1 teaches a high contrast grating as a reflector with diamond used as a heat spreader. The structure is, however, not amenable to mass production at wafer scale. Another structure that is also not amenable to mass production at wafer scale is known from PCT Application Publication No. WO 2005/036702 A2 in which a mechanical device is used to bring the amplifier medium into contact with the heat spreaders by means of pressure. Similarly, U.S. Pat. No. 6,385,220 B1 also teaches the use of a mechanical device to bring the amplifier medium into contact with the heat spreaders by means of pressure (“ . . . in physical contact with, but not bonded to . . . ”).

European Patent No. EP 1 720 225 B1 teaches a complete amplifier chip with a Bragg mirror (DBR) and a substrate. The substrate is either completely present or has an aperture. There is no plasma-activated wafer bonding, but purely mechanical contact or liquid capillary bonding.

European Patent No. EP 2 996 211 A1 teaches a solid-state laser active medium comprising an optical gain material and a heat sink, wherein the heat sink is transparent. A Bragg mirror (DBR) is present between the amplifier medium and either the heat spreader or an external mirror. This leads either to reduced heat dissipation from amplifier media or requires a limitation of the distance between pump optics and amplifier medium.

The afore-mentioned publication by Z. Yang et al., “16 W DBR-free membrane semiconductor disk laser with dual-SiC heatspreader”, Electronics Letters, vol. 54, no. 7, pp. 430-432 (2018) fails to teach the use of dielectric coatings, and has no reference to dielectric coating with different functions at two different wavelengths. The optically pumped, vertically emitting laser in this publication is pumped obliquely from the side. The amplifier unit is clamped in a holder.

Cho et al., “Compact and Efficient Green VECSEL Based on Novel Optical End-Pumping Scheme,” IEEE Photonics Technology Letters, vol. 19, no. 17, pp. 1325-1327 (2007), fails to teach the removal of the substrate. The light from the pump is pumped through the substrate. A diamond heat spreader is not bonded using plasma activation to the heat spreader but using liquid capillary bonding. It is not possible to mass produce the semiconductor disk laser at wafer scale.

### SUMMARY OF THE INVENTION

The semiconductor membrane laser described herein overcomes the prior art issues of the limited geometrical possibilities for pumping semiconductor membrane lasers and at the same time enables a low-cost, mass-production process of the entire amplifier unit.

The disclosure describes a novel laser concept (back-pumped semiconductor membrane laser) which enables a special pump geometry.

In one aspect the present invention relates to a semiconductor membrane laser chip. The semiconductor membrane laser chip comprises a planar-shaped lasing medium comprising an upper surface and comprising a lower surface. The lower surface is opposite to the upper surface. The lasing medium is configured to emit electromagnetic radiation at a laser wavelength λ₁. The semiconductor membrane laser chip further comprises a first heat spreader arranged or bonded to one of the upper surface and the lower surface of the lasing medium and further comprises a first dielectric layer arranged on the lower surface of the lasing medium. Alternatively, the first dielectric layer is arranged on a lower surface of the heat spreader when the first heat spreader is bonded to the lower surface of the lasing medium. Here, the first dielectric layer is arranged on that surface of the heat spreader that faces away from the lasing medium.

In either way and with both alternative approaches the first dielectric layer is reflective for the laser wavelength λ₁. Typically, the first dielectric layer is highly reflective for the laser wavelength λ₁. Typically, the first dielectric layer exhibits a reflectivity of at least 95%, of at least 97%, of at least 99%, of at least 99.5% or of at least 99.9% for the laser wavelength.

With typical implementations the first dielectric layer provides a mirror or mirroring surface of the cavity of the semiconductor membrane laser chip. The first dielectric layer can be suitably designed so as to enable an optical pumping of the lasing medium through the respective dielectric layer. This way, a distance and a rather close arrangement between a pump laser or pump laser beam and the semiconductor membrane laser chip can be optimized, e.g. reduced.

With some examples and by making use of an appropriately designed first dielectric layer being reflective for the laser wavelength and being at least partially transmissive for the electromagnetic radiation emitted by the pump laser a so-called backside-pumped (or back-pumped) semiconductor membrane laser chip can be provided. Consequently, the direction of a laser beam provided by a pump source or pump laser can be substantially parallel to the direction of a laser beam emitted by the lasing medium of the semiconductor membrane laser chip.

Such a co-alignment is of particular benefit to miniaturize a respective laser arrangement as well as to get rid of eventual focusing or collimating optical elements that were indispensable so far for focusing or collimating the pump laser onto or into the lasing medium of semiconductor membrane laser chips.

Typically, the lasing medium comprises numerous layers of different semiconducting materials or material combinations. The heat spreader typically comprises a planar shaped single-crystalline material which exhibits a well-defined thermal conductivity and provides dissipation of thermal energy generated or released in the lasing medium. Typically, also the first dielectric layer comprises numerous individual layers of different materials by way of which a dielectric layer structure is provided featuring a well-defined and predetermined degree of optical reflectivity, in particular for the laser wavelength.

According to a further example the laser or lasing medium is configured to emit the electromagnetic radiation at the laser wavelength when optically pumped by electromagnetic radiation of a pump wavelength λ₂. Typically, there is provided an optical source configured to generate and to emit electromagnetic radiation of a desired wavelength into or onto the lasing medium. With some examples the pump source comprises a pump laser, e.g. an edge-emitting laser diode or numerous laser diode bars.

Typically, the first dielectric layer is at least partially transparent for the pump wavelength λ₂. This way, the lasing medium can be optically pumped by electromagnetic radiation of the pump wavelength λ₂ propagating through the first dielectric layer.

According to a further example the first dielectric layer is transmissive for electromagnetic radiation at the pump wavelength λ₂. Hence, the first dielectric layer exhibits a comparatively high degree of reflectivity for the laser wavelength and, at the same time exhibits a sufficient transmissivity for electromagnetic radiation of the pump wavelength λ2. In this way the first dielectric layer provides a twofold function. On the one hand, it serves as a mirror or mirroring layer of the cavity of the semiconductor membrane laser chip. On the other hand, it is at least partially transmissive for electromagnetic radiation of the pump wavelength λ₂. Hence, the lasing medium of the semiconductor membrane laser chip can be pumped through the first dielectric layer.

Typically, the pump wavelength is shorter or smaller than the laser wavelength. Typically, the pump wavelength is shorter or smaller by at least 20 nm compared to the laser wavelength of electromagnetic radiation generated or emitted by the lasing medium when appropriately pumped with electromagnetic radiation at the pump wavelength.

With some examples the laser wavelength is between 850 nm-1200 nm. Here, the pump wavelength may be about 808 nm. With other examples the laser wavelength is in a range between 630 nm-790 nm. Here, the pump wavelength may be about 520 nm.

According to a further example the first dielectric layer comprises a first degree of transmissivity T1 for the laser wavelength λ₁ and further comprises a second degree of transmissivity T2 for another, hence a third wavelength λ₃. The second degree of transmissivity T2 is larger than the first degree of transmissivity T1 and the third wavelength λ₃ is smaller or shorter than the laser wavelength λ₁.

In other words, and in view of the laser wavelength λ₁, for which the first dielectric layer comprises a comparatively high degree of reflectivity, the first dielectric layer has a reduced degree of reflectivity for electromagnetic radiation at a wavelength smaller than the laser wavelength λ₁. This way, the first dielectric layer exhibits a comparatively high degree of reflectivity especially for the laser wavelength λ₁ and has a desired degree of reduced reflectivity and hence a sufficient degree of transmissivity for the pump wavelength λ₂.

In the context of the present invention, it should be noted, that lower and upper surfaces of the laser medium, of the heat spreader, of the dielectric layer and/or of a substrate or any other layers are only synonyms for opposite surfaces of the respective layers or layer structures. Generally, the semiconductor membrane laser chip may be oriented upside down. Then, a lower surface transforms into an upper surface; and vice versa. Generally, an upper surface of layer or medium may be regarded as a first surface and a lower surface of the respective layer or medium may be regarded as a second surface opposite the first surface.

According to a further example the semiconductor membrane laser chip further comprises a second dielectric layer arranged on the upper surface of the lasing medium or arranged on an upper surface of the at least one heat spreader. The second dielectric layer is arranged on the upper surface of the lasing medium when the heat spreader is arranged on or bonded to the lower surface of the lasing medium. The second dielectric layer is arranged on the upper surface of the at least one heat spreader when the at least one heat spreader is bonded to the upper surface of the lasing medium. Here, the second dielectric layer is arranged or deposited on the upper surface of the heat spreader facing away the upper surface of the lasing medium located underneath.

The second dielectric layer comprises a well-defined transmissivity for the laser wavelength λ₁. With regard to the laser wavelength λ₁ the second dielectric layer comprises an increased degree of transmissivity compared to the first dielectric layer. Hence, the transmissivity of the second dielectric layer is larger than the transmissivity of the first dielectric layer with regard to the laser wavelength λ₁. While the first dielectric layer is highly reflective for the laser wavelength λ₁ the second dielectric layer may be highly transmissive for the laser wavelength λ₁. Typically, the second dielectric layer serves or behaves as a kind of an anti-reflection coating of the layer stack of the semiconductor membrane laser chip to avoid any intra-cavity reflections of the semiconductor membrane laser chip.

According to a further example the semiconductor membrane laser chip further comprises a second heat spreader bonded to the other one of the upper surface and the lower surface of the lasing medium. With some examples and when the first heat spreader is bonded to the upper surface of the lasing medium the second heat spreader is bonded to the lower surface of the lasing medium. With some examples, wherein the first heat spreader is bonded to the upper surface of the lasing medium and wherein the first dielectric layer is arranged on the lower surface of the lasing medium the second heat spreader is arranged on a lower surface of the first dielectric layer facing away the lasing medium.

With other examples it is even conceivable, that the lasing medium is directly or indirectly sandwiched between a first heat spreader and a second heat spreader. Here, the first dielectric layer is deposited or arranged on an outside surface of the first or second heat spreader facing away the lasing medium. With some examples it is conceivable, that the lasing medium is sandwiched between a first and a second heat spreader and that the first and second heat spreaders are at least partially sandwiched by first and second dielectric layers.

In effect, and with some examples the layer stack of the semiconductor membrane laser chip may comprise the first dielectric layer as a bottom layer. On top of the first dielectric layer there may be provided one of the first and second heat spreaders. On top of the respective heat spreader there may be provided the lasing medium. On top of the lasing medium there may be provided the other one of the first and second heat spreaders and at the top of the respective heat spreader there may be provided the second dielectric layer.

According to a further example the semiconductor membrane laser chip comprises at least a first contact layer, e.g. implemented as a first metal contact layer. The first contact layer is adjacently arranged to one of the upper surface and the lower surface of the lasing medium. Alternatively, the first contact layer is adjacently arranged to a surface of one of the first heat spreader and the second heat spreader, which surface faces away from the lasing medium. The first contact layer typically comprises a metal or metal layer and serves to provide a good thermal contact with the heat spreader and/or with the lasing medium so as to facilitate dissipation of thermal energy released or generated by the lasing medium when optically pumped with electromagnetic radiation of the pump wavelength λ₂.

With some examples there is only provided a single contact layer arranged directly adjacent to one of the heat spreaders and the lasing medium.

With a further example of the semiconductor membrane laser chip at least one of the first contact layer and a second contact layer comprises an opening, aperture or recess in which one of the first and second dielectric layers is arranged. With some examples almost the entirety of an outside surface of the lasing medium and/or of the heat spreader may be covered by the contact layer. Only in the active lateral region of the lasing medium, i.e. that region of the layer of the lasing medium optically pumped by electromagnetic radiation of the pump wavelength λ₂ and/or emitting the radiation at the laser wavelength λ₁ there will be provided an aperture or opening in the respective contact layer so as to enable unobstructed optical pumping of the lasing medium and/or unobstructed emission of radiation at the laser wavelength λ₁.

Typically, the first and second dielectric layers can be selectively provided only in the region of the opening or aperture in the first and/or second contact layer.

According to a further example at least one of the first contact layer and the second contact layer comprises a metal contact layer configured for fastening, fixing or soldering to a mount or submount. Typically, the submount or mount for the semiconductor membrane laser chip comprises a metal body. This way and when appropriately fixed or mounted to the submount at least one of the first contact layer and the second contact layer may form a direct mechanical contact with the metal body of the respective mount. In this way thermal energy can be easily transferred or dissipated from the metal contact layer towards and into the metal body of the submount.

Thermal energy released from the lasing medium can be thus rather effectively transferred from the lasing medium into at least one of the first and second heat spreaders as well as into at least one of the first and second contact layers and finally into the metal body of the mount. This provides an improved thermal management of the semiconductor membrane laser chip.

According to a further example the mount or submount is provided with a metal body having a recess sized to receive a stack of layers at least including the lasing medium, the first heat spreader and the first dielectric layer therein. With some examples, the depth of the recess of the metal body is substantially equal to the thickness of the layer stack of the semiconductor membrane laser chip. This way, the layer stack can be mounted flush in the metal body, thus allowing for an improved mechanical assembly and fixing of the layer stack and the metal body. The backside of the metal body substantially flushing with an outside surface of the layer stack may be provided with a soldering foil or holding plate covering at least a portion of the metal body of the submount and covering at least a portion of the layer stack.

In a further aspect the present invention provides a laser arrangement. The laser arrangement comprises a semiconductor membrane laser chip as described above and a pump laser or a pump source configured to emit electromagnetic radiation at a pump wavelength λ₂. Here, the pump laser or the pump source is arranged and configured to emit the electromagnetic radiation at the pump wavelength λ₂ through the first dielectric layer into the lasing medium of the above-mentioned semiconductor membrane laser chip. Typically, the semiconductor membrane laser chip comprises an upper surface from which the laser radiation at the laser wavelength λ₁ is transmitted. The semiconductor membrane laser chip further comprises a lower surface, into which the electromagnetic radiation of the pump laser or pump source is coupled into the layer stack of the semiconductor membrane laser chip.

This way, a backside-pumped semiconductor membrane laser chip can be provided. The pump radiation, e.g. in the form of a pump beam, may propagate co-axial to the laser radiation produced or generated by the semiconductor membrane laser chip. This allows for a rather efficient implementation and, e.g. for a miniaturization of the laser arrangement. The pump laser or a pump source can be arranged in close vicinity to the layer stack of the semiconductor membrane laser chip. It may be arranged at a distance of less than 1 mm, less than 500 μm, less than 200 μm, less than 100 μm or even less than 50 μm.

The pump laser or the pump source may be even arranged without any substantial gap and hence in close vicinity to a backside of the semiconductor membrane laser chip.

Of course, the laser arrangement further comprises an external mirror for coupling the laser beam out of the semiconductor membrane laser. The external cavity mirror and the pump laser may be provided on opposite sides of the layer stack of the semiconductor membrane laser chip.

According to a further example the pump laser comprises at least one or several edge-emitting laser diodes. Alternatively, the pump laser comprises at least one or several laser diode bars. With such laser diodes or laser diode bars exhibiting a rather oval beam profile at an exit face of the laser diode the distance between the respective laser diode and the lasing medium of the semiconductor membrane laser chip can be selected such that a rather round or circular symmetric beam profile as emitted by the laser diode is present on or in the lasing medium of the semiconductor membrane laser chip. As the beam of the laser diode propagates, a rather elliptic beam profile with a long-axis in a first transverse direction changes into a rather circular symmetric profile and—as the beam propagates further—changes into an elliptic beam profile with another long-axis along a second transverse direction, e.g. perpendicular to the first transverse direction.

By appropriately selecting the distance between a laser diode acting as a pump source and the lasing medium of the semiconductor membrane laser chip, any focusing optical components and/or collimating optical components between the pump source and the lasing medium may become obsolete and superfluous.

According to a further example of the laser arrangement an optical path between the pump laser and the semiconductor membrane laser chip is effectively void of collimating or focusing optical elements. In this way, a rather elaborate arrangement of such optical components can be avoided, thus allowing to reduce manufacturing costs for producing such laser arrangement.

According to another example the laser arrangement comprises the mount or submount with a metal body. The semiconductor membrane laser chip comprises at least one contact layer as described above. Here, with the laser arrangement the semiconductor membrane laser chip is arranged at or in the submount in such a way that the semiconductor membrane laser is or becomes thermally coupled to the metal body of the submount. Here, and in a final assembly configuration the contact layer, which may be implemented as a metal contact layer, may be in direct surface contact with a portion of the metal body. The respective metal surfaces in direct contact with each other provide a respective thermal coupling. With some examples, the thermal coupling between the contact layers and the metal body of the submount can be provided through soldering.

In another aspect the present invention provides a method of manufacturing a plurality of laser chips as described above. The method comprises the steps of providing a lasing medium on a substrate and arranging or forming a first heat spreader on the upper surface of the lasing medium, wherein the upper surface of the lasing medium faces away from the substrate. Thereafter and in a subsequent step the substrate may be removed. The residual layer stack may then only comprise or consist of the lasing medium and the heat spreader.

In a subsequent step a first dielectric layer is then arranged, e.g. deposited or bonded, on the lower surface of the lasing medium or on the upper surface of the first heat spreader. The upper surface of the first heat spreader faces away from the lasing medium. The lower surface of the lasing medium faces away from the upper surface of the lasing medium. Finally, and with some examples the lasing medium is sandwiched between a first heat spreader and a first dielectric layer. With other examples, it is the first heat spreader, which is sandwiched between the lasing medium and the first dielectric layer. Removal of the substrate may take place before or after deposition of the first dielectric layer on the layer stack. Removal of the substrate should take place after providing the first heat spreader on the lasing medium.

With some examples and when the lasing medium is provided on the substrate it is only the first heat spreader that is arranged or formed on the upper surface of the lasing medium. The first heat spreader typically comprises a mechanical stability that is somewhat comparable to the mechanical stability of the substrate. Thereafter and as the first heat spreader is applied on the upper surface of the lasing medium the substrate can be removed e.g. by a suitable etching process. Once the substrate has been removed from the lower surface of the lasing medium the lower surface of the lasing medium can then be provided with the first dielectric layer. Alternatively, the lower surface of the lasing medium could be also provided with a second heat spreader. A first and/or a second dielectric layer may then be provided on outside facing surfaces of the first heat spreader and/or the second heat spreader, respectively, which outside facing surfaces face away the lasing medium.

According to another example and when the first dielectric layer is arranged or formed on the upper surface of the lasing medium removal of the substrate may harm the mechanical integrity of the lasing medium because the first dielectric layer may not provide sufficient mechanical stability to the lasing medium or to the layer of the lasing medium. Here, there may be provided at least one further layer on top of the first dielectric layer so as to establish a layer stack of sufficient mechanical stability. Thereafter, the substrate may be removed from the lower surface of the lasing medium and the lower surface of the lasing medium may then be provided with the first heat spreader.

With another example there may be provided a substrate. On the substrate there may be provided or arranged the lasing medium. On top of the lasing medium there may be provided or formed the first heat spreader. On top of the first heat spreader there may then be formed the first dielectric layer. After or before deposition or arrangement of the first dielectric layer on the first heat spreader the substrate may be removed. Removing of the substrate finally enables unobstructed transmission of electromagnetic radiation of the pump wavelength λ₂ through the first dielectric layer, through the first heat spreader and into the lasing medium.

Removal of the substrate may be provided as soon as the layer of the lasing medium is mechanically stabilized, typically by providing or forming the at least one heat spreader on the lasing medium. Typically, and with some examples, first and second heat spreaders are provided on opposite sides of the lasing medium before the at least first dielectric layer is deposited or coated on the semiconductor membrane laser chip.

With other examples it is even conceivable to provide a heat spreader preform, i.e. a layer of a heat spreader coated or provided with the first dielectric layer. Concurrently, there may be provided a lasing medium preform, i.e. a substrate provided with the lasing medium. In a subsequent step, the heat spreader preform and the lasing medium preform may be bonded together, such that the lasing medium gets in direct or indirect thermal contact with the heat spreader. Thereafter and when the lasing medium is mechanically stabilized by the heat spreader the substrate can be removed.

Typically, and substantially with all examples, as described herein the heat spreaders are substantially transparent for the laser wavelength λ₁ and/or or for the pump wavelength λ₂. They only exhibit a negligible degree of absorption for the respective wavelengths.

According to a further example of the method the substrate comprises a wafer of a predetermined wafer size. The wafer may comprise a diameter of at least 2 inches, of at least 3 inches, of at least 4 inches or it may be even larger than 5 or 10 inches in its planar diameter.

The lasing medium, the first heat spreader and the first dielectric layer extend across the surface of the wafer and form a wafer layer stack, hence a layer stack of wafer size. Manufacturing of the plurality of laser chips includes dicing the wafer layer stack into individual laser chips. Typically, the laser chips are of quadratic or rectangular size. By generating the wafer layer stack and by dicing individual laser chips from the wafer layer stack there can be provided a rather efficient method of producing a large quantity of semiconductor membrane laser chips.

In another aspect the semiconductor membrane laser chip has a lasing medium with a first heat spreader bonded to an upper surface of the lasing medium, a first contact layer arranged on an upper surface of the first heat spreader and having a first opening in which a first dielectric layer is arranged. A second contact layer is arranged on a lower surface of the lasing medium and has a second opening in which a second dielectric layer is arranged. The first dielectric layer and the second dielectric layer can be made of multiple layers.

This arrangement enables the pump beam to impinge perpendicularly to the amplifier medium in the active region of the semiconductor membrane laser. The focusing lens of the pump optics (or a system consisting of several lenses) can be placed close to the amplifier medium and is not limited in its lateral size since an angle of 180° is available. Therefore, a cheap pump source with a poor beam profile (or fiber coupled with a correspondingly large fiber diameter) can be used as the pump laser. The pump power is focused into the plane of the amplifier medium via the corresponding pump optics.

In another aspect, the semiconductor membrane laser chip includes an additional, second heat spreader bonded between a lower surface of the lasing medium and the second contact layer to provide more thermal dissipation.

With some examples the first heat spreader and/or the second heat spreader is selected from the group of thermally conductive materials comprising silicon carbide, diamond, or aluminum oxide.

With some examples the active or lasing medium is selected from the group of semiconducting materials comprising or consisting of AlGaInAsP (including AlGaAs, InGaAs and AlGaInP), AlInGaN, or AlGaInAsSb or AlGaInNAs, but this is not limiting of the invention.

The semiconductor membrane laser chip can be incorporated into a laser arrangement with a pump laser arranged to pump a pump beam of laser light through one of the first opening or the second opening. The laser chip is arranged in a submount to provide contact to the semiconductor membrane as a heat sink to improve thermal management. The submount is soldered to at least one of the upper heat spreader or the lower heat spreader. The pump laser is, for example, an edge emitting laser diode.

In a further aspect the present invention also provides a method of manufacture of a plurality of laser chips which comprises:
providing a laser medium on a substrate;
bonding a first heat spreader on a top surface of the lasing medium;
removing the substrate;
selectively applying a dielectric layer on the top surface of the first heat spreader; and
selectively applying a metallization layer on the top surface of the first heat spreader.

In a further aspect, a second heat spreader can be bonded on a bottom surface of the laser medium and a dielectric layer and/or a metallization layer applied to the bottom surface of the second heat spreader.

The method then comprises dicing the laser chips into one or more individual elements.

These laser chips can be subsequently soldered to a submount.

The aim of this invention is the cost-effective production of compact laser sources which offer advantages over existing alternatives with respect to output power and/or beam profile and/or attainable emission wavelength.

According to further aspect there is also provided a semiconductor membrane laser chip, a laser arrangement as well as methods of manufacturing a plurality of semiconductor membrane laser chips according to the present invention.

### BRIEF DESCRIPTION OF THE DRAWING FIGURES

FIG. 1 shows a semiconductor disk laser with a flip-chip process according to the prior art.

FIG. 2 shows a semiconductor disk laser with an intra-cavity heat spreader according to the prior art.

FIG. 3 shows an inclined pumped semiconductor membrane laser according to the prior art.

FIG. 4 shows an example of a back-pumped semiconductor membrane laser according to the present invention.

FIG. 5 shows a cross-section of the amplifier unit of the back-pumped semiconductor membrane laser.

FIG. 6 shows a partial section of a production of a large number of amplifier units on wafer scale.

FIG. 7 shows in cross-section an exemplary setup of a laser resonator with complete amplifier unit on a submount.

FIGS. 8a and 8b show in cross-section the amplifier unit for a compact component with integrated edge-emitting diode as pump source.

FIG. 9 shows a further example of the amplifier unit in which a submount is mounted on one side of the semiconductor membrane laser chip.

FIG. 10 shows a flow diagram of a manufacturing process for producing an amplifier unit.

FIG. 11 shows an example of a process of manufacturing a layer stack for producing semiconductor membrane laser chips.

FIG. 12 shows another example of a process of manufacturing a layer stack for producing semiconductor membrane laser chips.

FIG. 13 shows a further example of a process of manufacturing a layer stack for producing semiconductor membrane laser chips.

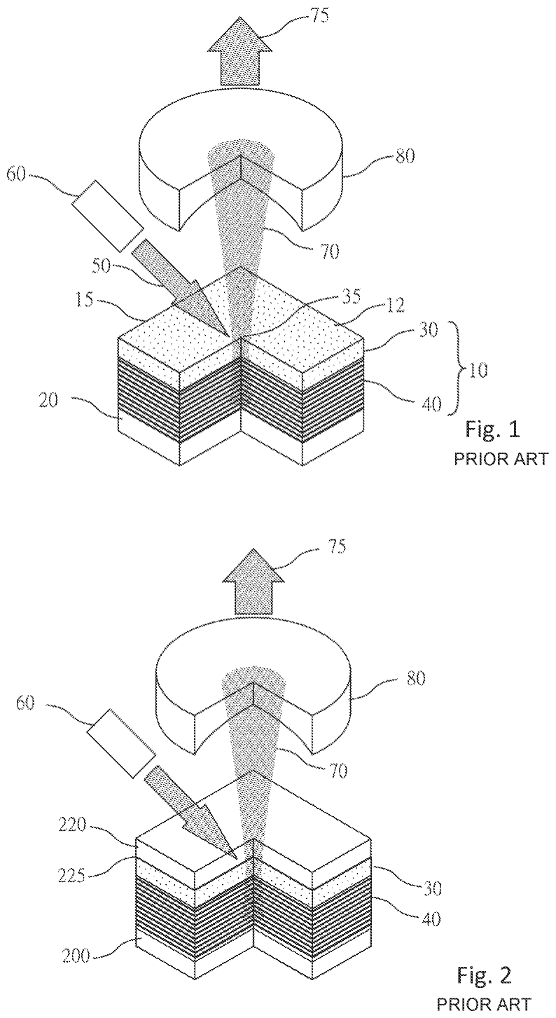

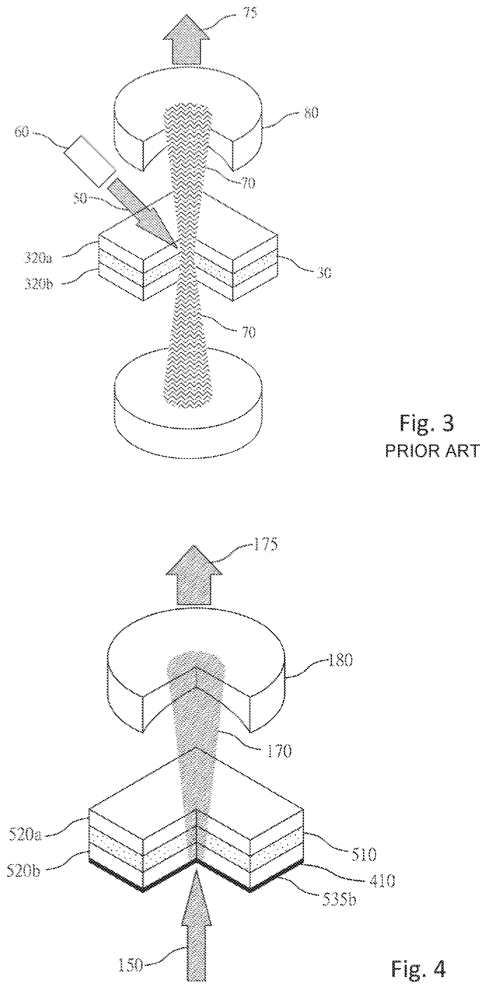

### DETAILED DESCRIPTION OF THE INVENTION

The invention will now be described on the basis of the drawing figures. It will be understood that the embodiments and aspects of the invention described herein are only examples and do not limit the protective scope of the claims in any way. The invention is defined by the claims and their equivalents. It will be understood that features of one aspect or embodiment of the invention can be combined with a feature of a different aspect or aspects and/or embodiments of the invention.

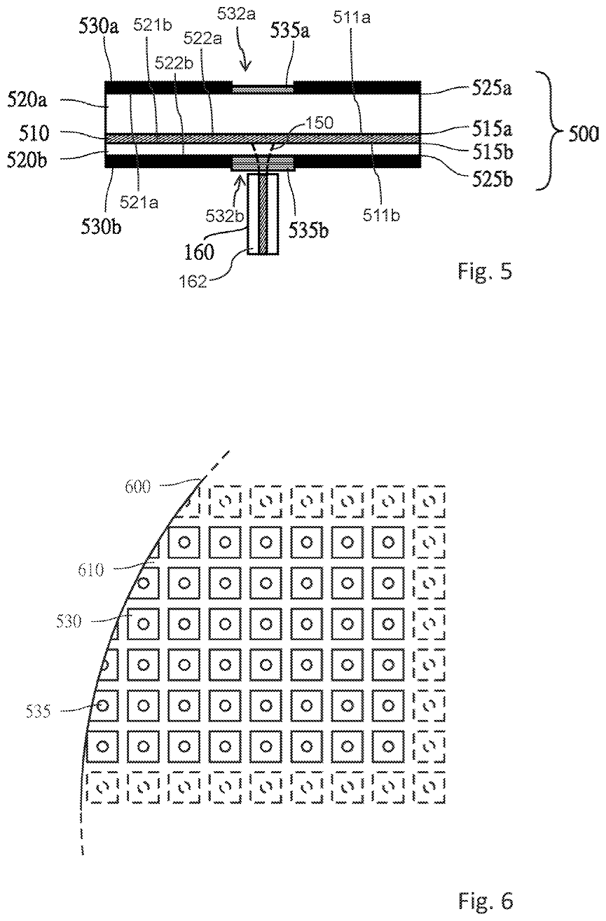

FIG. 4 shows an example of the semiconductor membrane laser according to the present invention implemented as a back-pumped semiconductor membrane laser. Here, the lasing medium 510 is pumped by radiation 150 of a pump laser 160 (see FIG. 5) from the back of the semiconductor membrane laser. A second heat spreader 520b is coated with a coating 410 which is transparent to light from the pump laser 160 but reflects light of the wavelength of the light generated in the active region, i.e. in a lasing or amplifier medium 510. The lasing medium 510 and hence the layer stack of the lasing or amplifier medium 510 is sandwiched by a first heat spreader 520a and the second heat spreader 520b. A lower surface of the second heat spreader 520b, i.e. facing away from the lasing medium 510, is provided with the coating 410. Typically, the coating 410 is provided or formed by a dielectric layer 535b.

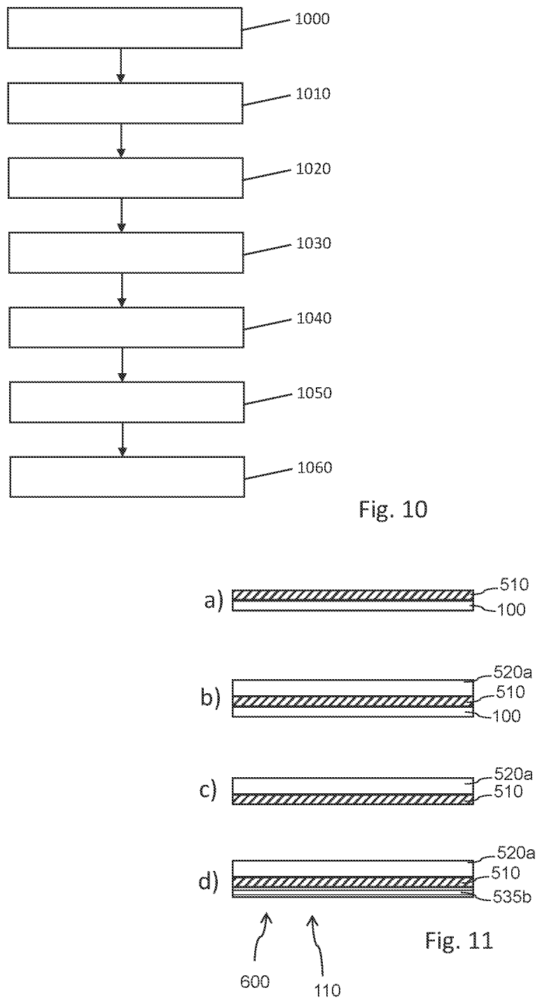

FIG. 5 shows an example of the semiconductor membrane laser 500 according to one aspect of the invention. The steps of the manufacturing process for the semiconductor membrane laser 500 are illustrated in FIG. 10. It will be appreciated that the steps set out in FIG. 10 and explained below are merely exemplary. In particular, the order of some of the steps could be changed.

The semiconductor membrane laser 500 comprises a semiconductor amplifier or lasing medium 510 (which is also called semiconductor membrane) which is located between an upper or first heat spreader 520a and a lower or second heat spreader 520b and selectively applied dielectric layers 535a,b and metal contact layers 530a,b. The semiconductor amplifier medium 510 is created by depositing a layer stack of semiconductor material on a substrate in step 1000 of FIG. 10 using an epitaxial process. It will be appreciated that the terms “upper” and “lower” used in this description are merely used to distinguish different elements shown in the drawing figures.

With the presently illustrated example the planar-shaped lasing medium 510 is sandwiched between the first and second heat spreaders 520a, 520b. Here, an upper surface 511a of the lasing medium 510 is in contact with a lower surface 522a of the first heat spreader 520a. A lower surface 511b of the lasing medium 510 is in contact with an upper surface 521b of the second heat spreader 520b. An upper surface 521a of the first heat spreader 520a facing away the lasing medium 510 is provided with the second dielectric layer 535a and with the first contact layer 530a. A lower surface 522b of the second heat spreader 520b is provided with or is in contact with the first dielectric layer 535b and with the second contact layer 530b.

The first and the second contact layers 530a, 530b may each comprise an opening or recess 532a, 532b in the layer structure extending all through the thickness of the respective first and second contact layers 530a, 530b. In the opening or recesses 532a, 532b there is provided the respective dielectric layer 535a, 535b. Since the contact layers 530a, 530b typically comprise a metal or are made of a metallic material the recesses or through openings extending through the contact layers 530a, 530b provide unobstructed optical beam propagation.

Examples of the semiconductor amplifier medium 510 include but are not limited to the following material systems:
AlGaInAsP (on GaAs substrate)—e.g. GaInAs quantum wells embedded in GaAs(P) barriers for laser emission in the near infrared spectral range (approx. 850-1200 nm).
AlGaInP (on GaAs substrate)—e.g. GaInP quantum wells embedded in AlGaInP barriers for laser emission in the red spectral range (approx. 630-700 nm).
AlInGaN (on GaN/Al₂O₃/SiC substrate)—e.g. InGaN quantum wells for laser emission in the blue/green spectral range (approx. 400-550 nm).
AlGaInNAs (on GaAs substrate)—e.g. GaInNAs quantum wells embedded in GaAs barriers for laser emission in the near infrared spectral range (>1200 nm).
GaAsSb (on GaSb substrate)—e.g. GaInAsSb quantum wells embedded in GaAs barriers for laser emission in the short wavelength infrared spectral range (around 2 μm).
AlGaInAsP (on InP substrate)—e.g. GaInAs quantum wells embedded in AlGaInAs barriers for laser emission in the short wavelength infrared spectral range (around 1.6 μm).

The upper surface of semiconductor amplifier medium 510 is cleaned in step 1010 of FIG. 10 and then the upper heat spreader 520a is applied to the cleansed upper surface 511a of the semiconductor amplifier medium 510 by means of a plasma-activated bonding process to form a direct contact. The substrate is removed from the lower surface 511b of the semiconductor amplifier medium 510 in step 1020 of FIG. 10, for example by wet chemical etching, and, if required, in step 1030 of FIG. 10 the lower heat spreader 520b is attached to the lower surface 511b of the semiconductor amplifier medium 510 using the same bonding process.

The two heat spreaders, i.e. the upper heat spreader 520a and the lower heat spreader 520b, are brought as complete wafers by means of plasma-activated bonding processes into direct, monolithic contact in steps 1010 and 1030 of FIG. 10 with the semiconductor amplifier medium 510, which is also of wafer size. As a result of this direct contact, heat dissipation (i.e. dissipation of thermal energy) in operation from the amplifier medium 510 at the interfaces 515a and 515b between the amplifier medium 510 and the upper heat spreader 520a or the lower heat spreader 520b is substantially uninhibited.

The two heat spreaders 520a and 520b are made, for example of diamond or silicon carbide with good optical qualities to allow passage of the laser radiation. Silicon carbide (SiC) is monocrystalline and has a very high optical quality at wafer-size scale with good surface finish available. Its thermal conductivity can be up to 400 W/mK. Diamond is also monocrystalline, but currently does not yet have a high optical quality with good surface finish available at wafer scale but has a very good thermal conductivity of up to 2000 W/mK.

Aluminum oxide (monocrystalline) can also be used and has very high optical quality with good surface finish available at wafer scale, but with a low thermal conductivity of only ˜25 W/mK.

The combination of the semiconductor amplifier medium 510 and the heat spreaders 520a and 520b are termed a “wafer layer stack” 110 (as shown in FIGS. 11-13).

Subsequently in step 1040 of FIG. 10, the top 525a and the bottom 525b of the wafer layer stack are selectively provided with dielectric layers 535a and 535b by deposition or metal contact layers 530a and 530b by metallization using lithography or shadow masks. As can be seen in the wafer 600 shown in FIG. 6, individual—here shown in a circle—surfaces (light-opening window or aperture) are provided with the dielectric layers 535 and the adjacent surrounding area—here shown in a square—is provided with the metal contact layers 530. Between the metal contact layers 530, so-called sawing lines 610 remain uncoated along the lines in which the sawing or splitting process in step 1050 of FIG. 10 for separation or dicing of the semiconductor membrane laser chips takes place later. In a non-limiting example, the wafer 600 is a 4-inch wafer and the edge length of the amplifier unit of 1.5 mm and a width of the saw lines of 0.1 mm results in approx. 3,000 semiconductor membrane laser chips as amplifier units.

It will be seen that the deposition of the dielectric layers 535a and 535b as well as the metal contact layers 530a and 530b takes place symmetrically on both the top 525a and the bottom 525b of the wafer layer stack. However, the dielectric layers 535a and 535b have different functions on the two sides as will now be explained. The bottom of the wafer layer stack is assumed to be the direction from which the pump light 150 is received (as shown in FIGS. 4 and 5). The function of the upper or second dielectric layer 535a deposited on the upper heat spreader 520a may be to enable a high transmission at the wavelength λ₁ of the generated laser mode in the amplifier medium 510. On the other hand, the function of the lower or first dielectric layer 535b applied to the lower heat spreader 520b is to enable a high reflection at the wavelength λ₁ of the generated laser mode in the amplifier medium 510 and a high transmission at the wavelength λ₂ of the pump laser 160 used to pump the amplifier medium 510. Alternatively, the lower or first dielectric layer 535b is arranged to reflect light at the wavelength λ₂ of the pump laser 160 used to create a resonator for the pump wavelength, and thus an increased absorption efficiency. The material used in the dielectric layers 535a,b can be SiO₂, Nb₂O₅, HfO₂ TiO₂, Al₂O₃ and Ta₂O₅, but this is not limiting of the invention.

It was noted above that the order of the manufacturing steps set out in FIG. 10 is not limiting of the invention. For example, the deposition of the dielectric layers 535a and 535b as well as the metal contact layers 530a and 530b can be changed and will depend on the design of the semiconductor membrane chip. Similarly, the bonding of the substrate and the subsequent removal of the substrate may be carried out in a different order. It would also be possible to apply the dielectric layers 535a and 535b after dicing of the semiconductor membrane chips.

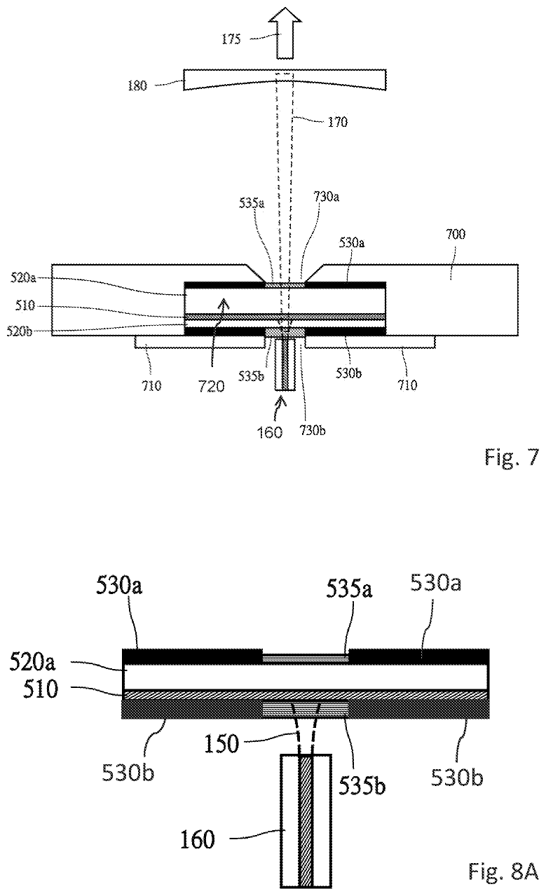

Finally, the individual ones of the semiconductor membrane laser chips are fixed or soldered in step 1060 of FIG. 10 to a submount 700, as shown in FIG. 7 using a soldering process—e.g. using a pre-formed soldering foil 710 or any other metallic fasteners, e.g. in form of a metallic plate. Alternatively, the solder can be previously deposited on the submount 700 or on the semiconductor membrane laser chip. This submount 700 comprises a metal body, such as but not limited to, copper or brass, which may or may not be coated with gold. The metal body has a high thermal conductivity and has a recess 720. The recess 720 is adapted to the thickness of the semiconductor membrane laser chips and the thickness of the soldering foil 710 in such a way that the semiconductor membrane laser chip is flush with the surface of the submount 700 on the other side and therefore the metal contact layer 530b can be connected to the submount 700 via another soldering foil 710 or metallic fastener.

The submount 700 has an upper window 730a and a lower window 730b which align respectively with the upper dielectric layer 535a and the lower dielectric layer 535b such that the dielectric layers 535a and 535b remain optically freely accessible through the recess 720 and enable light to pass through the submount 700. The heat or thermal energy from both sides of the upper heat spreader 520a and the lower heat spreader 520b is dissipated to the submount 700, since the remaining area of the upper and lower sides of the semiconductor membrane laser chip is available for the heat transfer between the upper heat spreader 520a and the lower heat spreader 520b and the submount 700.

The example shown in FIG. 7 is a linear resonator geometry with a single external mirror 180 coupling the laser beam 175 out of the semiconductor membrane laser. The design of the amplifier unit on the submount 700 allows good access to the amplifier medium 510 from both sides of the semiconductor membrane laser. The semiconductor membrane laser is pumped by a pump laser 160 which is able to focus a beam through the lower dielectric layer 535b to the amplifier layer 510 at an angle of 180°. This means that the lateral size of a focusing lens as part of the pump optics is not limited by the geometry of the submount 700. Preferably, an optical path between the pump laser 160 and the lasing medium 510 can be void of any optical components, such as a focusing of collimating optical arrangement. The optical path may be void of any refractive or diffractive optical elements. In an alternative arrangement, the individual ones of the semiconductor laser chips and the submount 700 can also be arranged so that the more accessible side of the submount 700 is on the side with the upper dielectric layer 535a, thus pointing in the direction of an output coupler mirror 180 and the outcoupled laser beam 170, in order to take advantage of the good accessibility for particularly compact resonator geometries.

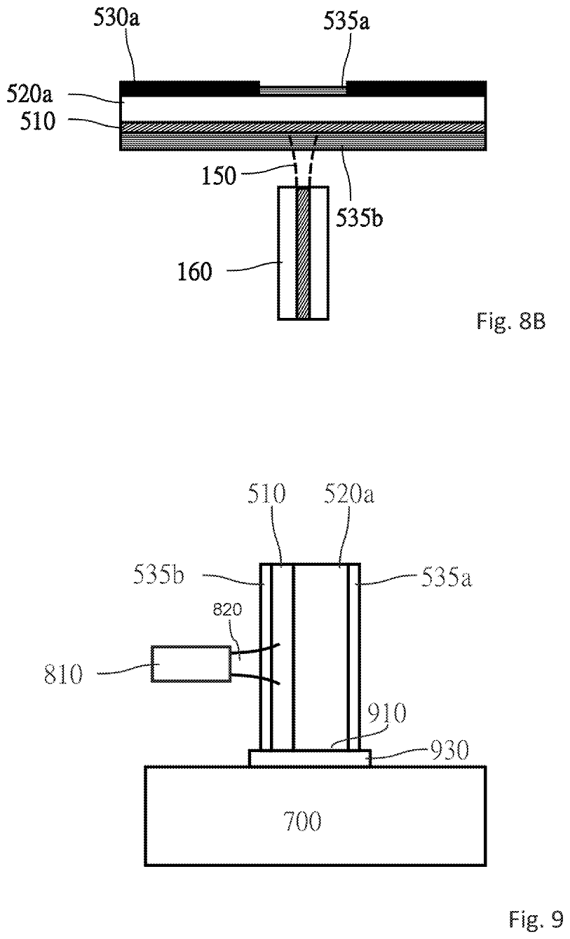

A similar concept is shown in FIG. 8A which only has a single upper heat spreader 520a and no lower heat spreader 520b compared to the designs shown in FIGS. 5 and 7. The lower and hence the first dielectric layer 535b and the lower metal contact layer 530b are applied directly to the amplifier medium 510. This design enables the placement of an edge-emitting laser diode 162 (see FIG. 5) as a pump source at a very small distance from the amplifier medium 510. The distance is selected depending on the emission profile of the edge-emitting laser diode 162 and the thickness of the lower dielectric layer 535b so that the pump beam 150 has a circular shape in the plane of the amplifier medium 510. At this defined distance (which has a typical optical path length in the range of 10 to 100 μm) the plane of the amplifier medium 510 is between the near field and the far field of the pump beam 150 and the beam diameters in the two beam dimensions of the pump beam “fast axis” and “slow axis” are the same. In this arrangement, no optics are required to focus the pump beam 150, which makes it possible to produce particularly compact and cost-effective components consisting of an amplifier unit with integrated pump source.

The semiconductor membrane laser shown in FIG. 8B also has no lower heat spreader 520b and further has no lower metal contact layer 530b. There is therefore also no need for a lower window through which the light from the pump laser 160 needs to pass.

FIG. 9 shows a further example of the semiconductor membrane laser in which the submount 700 is not located around the semiconductor membrane laser 500 but on one edge 910 of the semiconductor membrane laser 500. Solder 930 is placed on the edge 910 and a thermal connection between the submount 700 and the semiconductor membrane laser 500 established.

In a further aspect, a GRIN (graded refractive index) lens can be manufactured in such a way that the GRIN lens through which the pump beam 820 from a side emitting diode 810 passes is in direct contact with the upper dielectric layer 535a or the lower dielectric layer 535b. This reduces energy losses by enabling the pump laser light from the pump laser 160 to be focused in the plane of the active region with the amplifier medium 510.

It will be appreciated that the semiconductor membrane laser described in this disclosure may include further mirrors, such as those for a V-shaped or Z-shaped cavity. Furthermore, the generated laser beam 170 in the resonator may include further intra-cavity elements, such as non-linear crystals (e.g. SHG (second harmonic generation) crystals, birefringent filters (BRF), etalons, and absorbers).

One method of producing a laser chip is for instance illustrated in FIG. 11. Here, in step a) there is provided a substrate 100 with a layer of a lasing medium 510. In a subsequent step b) the layer of a first heat spreader 520a is arranged or formed on an upper surface 511a of the lasing medium 510. Thereafter and as illustrated in step c) the substrate 100 is removed and in a further step d) the first dielectric layer 535b is deposited or arranged on the lower surface 511b of the lasing medium 510 thus forming a multi-layer stack 110 of wafer 600. Subsequently the multi-layer-stack is cut into individual laser chips 500 of appropriate transverse size. In general, the order of steps to be performed for manufacturing a multi-layer stack 110 may vary. A removal of the substrate 100 may only take place after the lasing medium 510 is mechanically stabilized, e.g. through application of a heat spreader 520a.

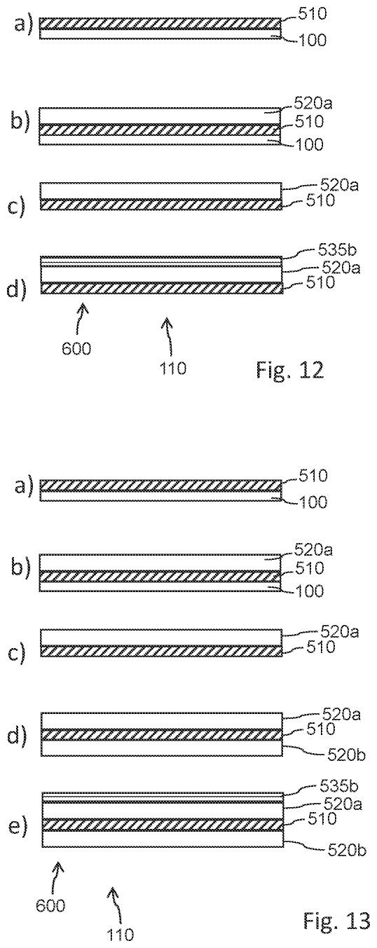

In FIG. 12 another way of manufacturing such laser chips 500 as described before is illustrated. Here, in step a) there is provided a substrate 100 with a layer of a lasing medium 510. In a subsequent step b) a first heat spreader 520a is arranged or formed on an upper surface 511a of the lasing medium 510. Thereafter and as illustrated in step c) the substrate 100 is removed and in a further step d) the first dielectric layer 535b is deposited or arranged on the upper surface of the first heat spreader 520a facing away the lasing medium 510 thus forming a multi-layer stack 110 of wafer 600. Subsequently, the multi-layer-stack 110 is cut into individual laser chips 500 of appropriate transverse size. Removal of the substrate 100 may also take place after deposition of the first dielectric layer 535b on the first heat spreader 520a. With some examples and contrary to the illustrated sequence of steps of FIG. 12 the first dielectric layer 535b may be deposited or coated on the first heat spreader 520a before the first heat spreader 520a is bonded or connected to the lasing medium 510. Further alternatively, the isolated first heat spreader 520a may be provided with the first dielectric layer 535b. The substrate 100 with the layer of the lasing medium 510 as illustrated in step a) of FIG. 12 may be separately prepared and may be then bonded with the first heat spreader 520a, which is prefabricated with the first dielectric layer 535b.

In FIG. 13 a further example of manufacturing a semiconductor membrane laser chip 500 comprising a multi-layer stack 110 of wafer 600 is schematically illustrated. Here, in step a) a substrate 100 is provided with a layer or with multiple internal layers of a lasing medium 510. Thereafter, as illustrated in step b) and on top of the lasing medium 510 there is provided the first heat spreader 520a. Thereafter and since the first heat spreader 520a provides mechanical stability to the lasing medium 510, the substrate 100 may be removed in step c). After removal of the substrate 100 a second heat spreader 520b is provided on that surface of the lasing medium 510 that faces away the first heat spreader 520a as shown in step d). Here, the second heat spreader 520b may be bonded to the lasing medium 510. Thereafter and as illustrated in step e) there is provided at least a first dielectric layer 535b on top of one of the first heat spreader 520a and the second heat spreader 520b.

1-20. (canceled)

21. A semiconductor membrane laser chip comprising:
a planar-shaped lasing medium having an upper surface and a lower surface opposite the upper surface, the lasing medium configured to emit an electromagnetic radiation at a laser wavelength λ₁;
a first heat spreader bonded to one of the upper surface and the lower surface of the lasing medium;
a first dielectric layer arranged on the lower surface of the lasing medium or arranged on a lower surface of the first heat spreader when the first heat spreader is bonded to the lower surface of the lasing medium, wherein the first dielectric layer is reflective for the laser wavelength λ₁.

22. The semiconductor membrane laser chip according to claim 21, wherein the planar-shaped laser medium is configured to emit the electromagnetic radiation at the laser wavelength λ₁ when optically pumped by an electromagnetic radiation of a pump wavelength λ₂.

23. The semiconductor membrane laser chip according to claim 22, wherein the first dielectric layer is transmissive for the electromagnetic radiation of the pump wavelength λ₂.

24. The semiconductor membrane laser chip according to claim 21, further comprising a second dielectric layer arranged on the upper surface of the lasing medium or arranged on an upper surface of the first heat spreader when the first heat spreader is bonded to the upper surface of the lasing medium, the second dielectric layer having a transmissivity for the laser wavelength λ₁ larger than a transmissivity of the first dielectric layer for the laser wavelength λ₁.

25. The semiconductor membrane laser chip according to claim 21, further comprising a second heat spreader bonded to the other one of the upper surface and the lower surface of the lasing medium.

26. The semiconductor membrane laser chip according to claim 25, further comprising a first contact layer adjacently arranged to one of the upper surface and the lower surface of the lasing medium or adjacently arranged to a surface of one of the first heat spreader and the second heat spreader, wherein the surface of the one of the first heat spreader and the second heat spreader faces away from the lasing medium.

27. The semiconductor membrane laser chip according to claim 26, further comprising a second contact layer adjacently arranged to the other one of the upper surface and the lower surface of the lasing medium or adjacently arranged to a surface of the other one of the first heat spreader and the second heat spreader, wherein the surface of the other of the first heat spreader and the second heat spreader faces away from the lasing medium.

28. The semiconductor membrane laser chip according to claim 27, wherein at least one of the first contact layer and the second contact layer has an opening or aperture in which a corresponding one of the first dielectric layer and the second dielectric layer is arranged.

29. The semiconductor membrane laser chip according to claim 27, wherein at least one of the first contact layer and the second contact layer comprises a metal contact layer configured for soldering to a submount, wherein the submount comprises a metal body.

30. The semiconductor membrane laser chip according to claim 21, further comprising a submount comprising a metal body having a recess sized to receive the lasing medium, the first heat spreader and the first dielectric layer therein.

31. The semiconductor membrane laser chip according to claim 25, wherein at least one of the first heat spreader and the second heat spreader comprises a thermally conductive material including at least one of silicon carbide, diamond and aluminum oxide.

32. The semiconductor membrane laser chip according to claim 21, wherein the lasing medium comprises a semiconducting material including at least one of AlGaInAsP, AlInGaN, AlGaInAsSb and AlGaInNAs.

33. The semiconductor membrane laser chip according to claim 24, wherein at least one of the first dielectric layer and the second dielectric layer comprises a dielectric material including at least one of SiO₂, Nb₂O₅, HfO₂, TiO₂, Al₂O₃ and Ta₂O₅.

34. A laser arrangement comprising:
a semiconductor membrane laser chip according to claim 21; and
a pump laser configured to emit an electromagnetic radiation at a pump wavelength λ₂;
wherein the pump laser is arranged and configured to emit the electromagnetic radiation through the first dielectric layer into the lasing medium.

35. The laser arrangement according to claim 34, wherein the pump laser comprises at least one edge-emitting laser diodes or wherein the pump laser comprises at least one laser diode bars.

36. The laser arrangement according to claim 34, wherein an optical path between the pump laser and the semiconductor membrane laser chip is void of collimating or focusing optical elements.

37. The laser arrangement according to claim 34, further comprising a submount comprising a metal body and wherein the semiconductor membrane laser chip comprises at least one contact layer thermally coupled to the submount by soldering.

38. A method of manufacturing a plurality of the semiconductor membrane laser chip according to claim 21, the method comprising:
providing the lasing medium on a substrate;
arranging or forming the first heat spreader on the upper surface of the lasing medium facing away from the substrate;
removing the substrate;
arranging or forming the first dielectric layer on one of the lower surface of the lasing medium facing away the first heat spreader and an upper surface of the first heat spreader facing away the lasing medium.

39. The method according to claim 38, further comprising:
arranging or forming a second heat spreader on the lower surface of the lasing medium when the first dielectric layer is arranged or formed on the upper surface of the first heat spreader.

40. The method according to claim 38, wherein the substrate comprises a wafer of a predetermined wafer size, wherein the lasing medium, the first heat spreader and the first dielectric layer extend across the wafer size and form a wafer layer stack, and wherein the method of manufacturing a plurality of the semiconductor membrane laser chips further comprises dicing the wafer layer stack into individual ones of the plurality of semiconductor membrane laser chips.
